(19) United States
(12) Patent Application Publication
(10) Pub. No.: US 2012/0113603 A1
(43) Pub. Date: May 10, 2012

(54) ELECTRONIC CIRCUIT DEVICE

(75) Inventor: Shigetomi TOKUNAGA, Osaka (JP)

(73) Assignee: Panasonic Corporation, Osaka (JP)

(21) Appl. No.: 13/245,914

(22) Filed: Sep. 27, 2011

(30) Foreign Application Priority Data
Nov. 8, 2010 (JP) JP 2010-249287

(51) Int. Cl. H05K 5/02

(52) U.S. Cl. 361/752

(57) ABSTRACT

An electronic circuit device includes a printed circuit board, a semiconductor element, a housing, multiple rubber bushings for underpinning the printed circuit board in a vertical direction, an aluminum plate placed vertically above the printed circuit board, and an insulating sheet. Mounting of the aluminum plate to the housing causes the printed circuit board to compress the rubber bushings, and bring the semiconductor element, the aluminum plate and the insulating sheet into pressed contact with one another.

### FIELD OF THE INVENTION

The present invention relates to an electronic circuit device including a housing that accommodates a printed circuit board, on which electronic components such as semiconductor elements are mounted.

### BACKGROUND OF THE INVENTION

A conventional electronic circuit device accommodates a printed circuit board, on which a semiconductor element is mounted, in a housing, and the semiconductor element is brought into solidly contact with a metal plate that forms an outer frame of the housing. The heat generated from the semiconductor element thus travels to the metal plate, and then is dissipated.

The conventional electronic circuit device is described hereinafter with reference to FIG. 7 that is a sectional view schematically showing a structure of the electronic circuit device disclosed in Unexamined Japanese Patent Application Publication No. 2004-134491.

As shown in FIG. 7, semiconductor element 102, e.g. an IPM (intelligent power module) for driving a motor, is mounted on printed circuit board 100 by soldering terminals 102a to board 100. Metal plate 105 is disposed such that it is brought into solidly contact with element 102. On top of that, printed circuit board 100 is fixed to housing 108 with screws 111, and an opening of housing 108 is covered with metal plate 105.

A top face of metal plate 105 is flush with a mounting face of housing 108, and this flush plane is brought into solidly contact with external radiator 115 with screws 114. Printed circuit board 100 is covered with cover 117.

Operation of the foregoing electronic circuit device is described hereinafter. When the electronic circuit device starts operating, semiconductor element 102 is powered and then generates heat. The heat travels to metal plate 105 kept solid contact with semiconductor element 102.

Since metal plate 105 is solidly mounted to external radiator 115, the heat travelling to metal plate 105 is further transferred to external radiator 115. Semiconductor element 102 thus never becomes too hot, and can be protected from thermal destruction. The electronic circuit device, therefore, can operate with the reliability being maintained.

However, the foregoing conventional structure has a problem, i.e. metal plate 105 adheres to external radiator 115, so that the electronic circuit device is never exposed to the outer air. In a case where the electronic circuit device is mounted to, e.g. a compressor which becomes hot, no effect of heat dissipation can be expected. If the electronic circuit device is mounted in a reverse direction, i.e. the electronic circuit device is mounted on the underside of cover 117, and then metal plate 105 can be exposed to the outer air, whereby the heat of metal plate 105 can be dissipated into the outer air.

However, since this structure allows metal plate 105 to be exposed, a user may touch metal plate 105. If semiconductor element 102 encounters a dielectric breakdown due to malfunction, metal plate 105 is electrically charged, and then the safety cannot be assured.

In a case where an ambient temperature changes, a difference in coefficient of linear expansion between housing 108 and element 102 will produce a gap between element 102 and plate 105, whereby the heat-transfer from semiconductor element 102 to metal plate 105 is impeded. On top of that, stress is applied to a junction between terminal 102a and printed circuit board 100, so that an electrical connection can be broken.

In a case where the electric circuit device is mounted to an oscillatory product, e.g. a compressor, the oscillation can travel to the mounted sections, fixed with screws 111, of printed circuit board 100 and also travels to terminals 102a, thereby sometimes inviting a mechanical breakdown.

### SUMMARY OF THE INVENTION

The present invention addresses the problems discussed above, and aims to provide an electronic circuit device comprising the following structural elements:

a printed circuit board having an upper face and a lower face both available for mounting components;

a semiconductor element mounted on the upper face of the printed circuit board;

a housing for accommodating the printed circuit board and having an opening in one of the surface;

a plurality of rubber bushings for underpinning, along a vertical direction, the printed circuit board disposed in the housing;

an aluminum plate disposed vertically above the printed circuit board and closing the opening; and

an insulating sheet disposed between the semiconductor element and the aluminum plate.

Mounting of the aluminum plate to the housing causes the printed circuit board to compress the rubber bushings, and bring the semiconductor element, the aluminum plate and the insulating sheet into pressed contact with one another.

The structure discussed above allows the semiconductor element to be positively insulated from the aluminum plate by the insulating sheet. In a case of a change in the ambient temperature, the rubber bushings allow maintaining the space constant between the printed circuit board and the aluminum plate because the compressibility ratio of the rubber bushings can change appropriately. The solid contact between the semiconductor element, the aluminum plate, and the insulating sheet can be thus maintained, and the semiconductor element is prevented from excessively rising in temperature. The electric circuit device with higher reliability thus can be provided.

The printed circuit board is flexibly supported by the rubber bushings relative to the housing, so that the electric circuit device can be mounted to an oscillatory product, e.g. a compressor, with the reliability improved, because the rubber bushings can absorb the oscillation, thereby preventing the components from breakdown.

### BRIEF DESCRIPTION OF THE DRAWINGS

FIG. 1 is an exploded perspective view of an electronic circuit device in accordance with an embodiment of the present invention.

FIG. 2 is a perspective view of a rubber bushing employed in the electric circuit device shown in FIG. 1.

FIG. 3 is a sectional view cut along line 3-3 in FIG. 2.

FIG. 4 is a plan view of an aluminum plate employed in the electronic circuit device in accordance with an embodiment of the present invention.

FIG. 5 is a sectional view cut along line 5-5 in FIG. 4.

FIG. 6 is a lateral view of an electronic circuit device mounted to a compressor in accordance with an embodiment of the present invention.

FIG. 7 is a sectional view illustrating schematically a structure of a conventional electronic circuit device.

### DETAILED DESCRIPTION OF PREFERRED EMBODIMENT

An exemplary embodiment of the present invention is demonstrated hereinafter with reference to the accompanying drawings. The present invention is not limited to this embodiment.

### Exemplary Embodiment

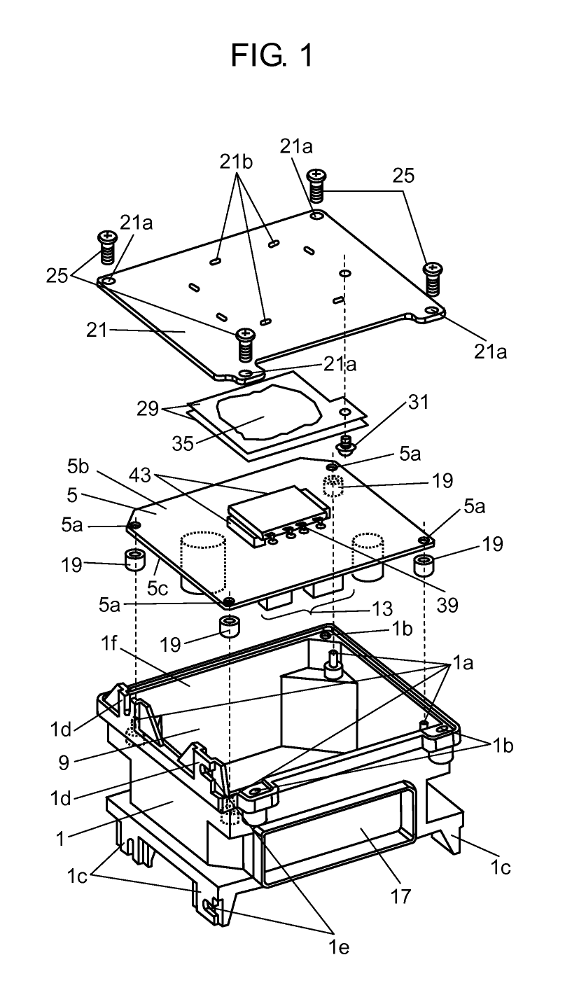

FIG. 1 is an exploded view of an electronic circuit device of the present invention. As shown in FIG. 1, the electronic circuit device comprises the following structural elements: printed circuit board 5, semiconductor element 39, housing 1, multiple rubber bushings 19, aluminum plate 21, and insulating sheet 29. Housing 1 includes opening 9, multiple legs 1c and ld to be used for mounting. Housing 1 is formed by injection-molding resin, e.g. denaturalized polyphenylene ether, and includes opening 9 in one of surface 1f. Opening 9 is slightly larger than printed circuit board 5 so as to accommodate board 5 inside housing 1. Holes 1e are provided to legs 1c and 1d for mounting the electronic circuit device.

Double-sided printed circuit board 5 has upper face 5b and lower face 5c, and both the faces are ready to be mounted with electronic components. Board 5 is formed of epoxy resin and glass fabric or glass non-woven fabric. Lower face 5c is mounted with connector 13, e.g. by soldering, and provided with multiple mounting holes 5a at the four corners. An opening is formed on housing 1 at a place corresponding to connector 13 so that the wires from connector 13 can be routed outside from this opening, which is hereinafter referred to as wire-outlet 17. Projections 1a are unitarily formed with and inside housing 1 at four places, and they protrude toward opening 9.

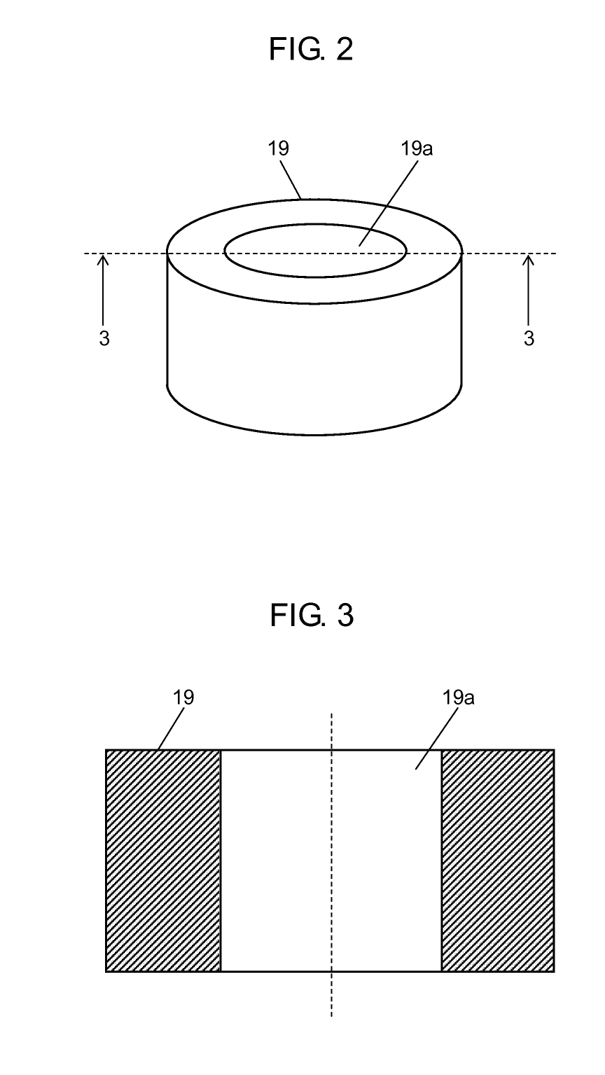

FIG. 2 is a perspective view of a rubber bushing of the electronic circuit device in accordance with this embodiment. FIG. 3 is a sectional view taken along line 3-3 in FIG. 2. Each one of projections 1a at the four places is provided with rubber bushing 19 having hollow 19a. In other words, projection la is fit into hollow 19a. As shown in FIG. 1, multiple rubber bushings 19 are disposed inside housing 1, and underpin the printed circuit board 5 along the vertical direction.

The height of projection 1a is greater than the height of rubber bushing 19, and the tip of projection 1a protrudes from bushing 19. The protruding section of projection 1a is fit into mounting hole 5a of board 5.

When printed circuit board 5 is accommodated in and mounted to housing 1, rubber bushings 19 are pinched between housing 1 and board 5, so that they are compressed. The diameter of each one of mounting holes 5a is so designed as to have an appropriate clearance with projection 1a inserted, for instance, projection 1a is 3 mm across, then mounting hole 5a is 4 mm across.

Mounting holes lb are formed at the corners of opening 9, and holes 21a are punched at the corners of aluminum plate 21 made of aluminum alloy. Aluminum plate 21 is disposed vertically above printed circuit board 5 and is fixed to housing 1 with screws 25, so that it can close opening 9.

Insulating sheets 29, e.g. laying two sheets on top of another, are solidly disposed on an underside of aluminum plate 21 with screw 31. Each one of insulating sheet 29 has electrical insulating performance satisfying the safety standard, e.g. durable to dielectric strength test of 1750 voltages for one minute.

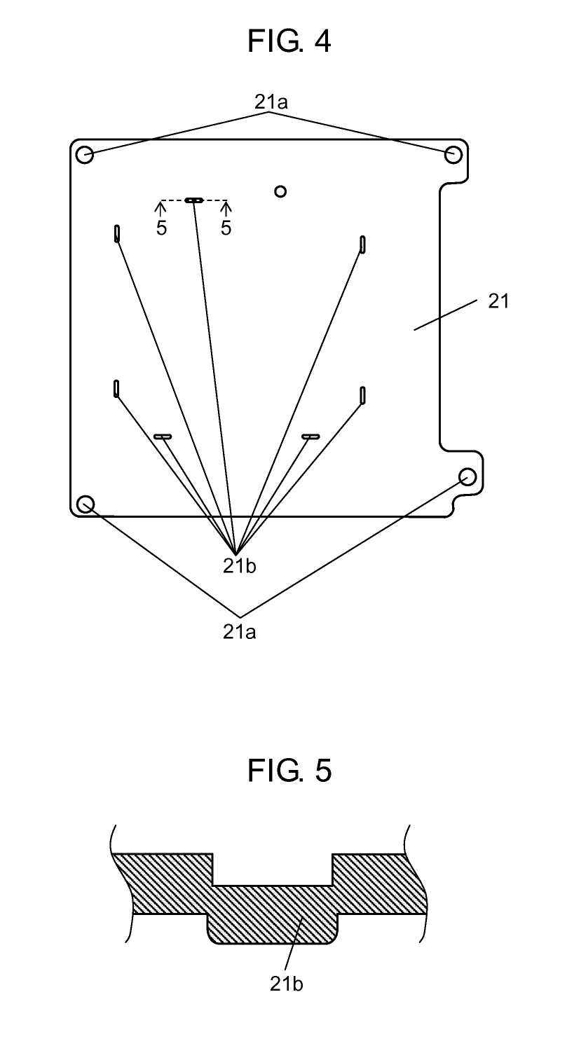

FIG. 4 is a plan view of the aluminum plate of the electronic circuit device in accordance with this embodiment. FIG. 5 is a sectional view taken along line 5-5 in FIG. 4. Multiple protrusions 21b are formed by press work on the underside of aluminum plate 21. As shown in FIG. 1, insulating sheets 29 are disposed on the underside of aluminum plate 21 at a section surrounded by protrusions 21b, which thus restrict the position of insulating sheets 29.

Insulating sheets 29 are coated in advance with thermo-diffusion compound 35 which is excellent in heat conductivity.

Thermo-diffusion compound 35 has a thermal conductivity of approx. 0.9 W/m·K, and is made of mixture of silicone oil and zinc oxide. Compound 35 not only improves the sold contact between insulating sheet 29 and aluminum plate 21 but also improves the heat conductivity between sheet 29 and plate 21.

On upper face 5b of board 5, semiconductor element 39, e.g. intelligent power module (IPM) for driving a compressor, is mounted. Other than the components such including connector 13, semiconductor element 39 only is mounted on upper face 5b confronting aluminum plate 21, i.e. on the opposite side to the other components. Spacer 43 is disposed solidly between semiconductor element 39 and printed circuit board 5.

Semiconductor element 39 is brought into solid contact with aluminum plate 21 on which insulating sheets 29 are disposed. In other words, insulating sheets 29 are sandwiched between element 39 and plate 21. Mounting of aluminum plate 21 to housing 1 causes printed circuit board 5 to compresses rubber bushings 19, and bring semiconductor element 39, aluminum plate 21 and insulating sheets 29 into pressed contact with one another.

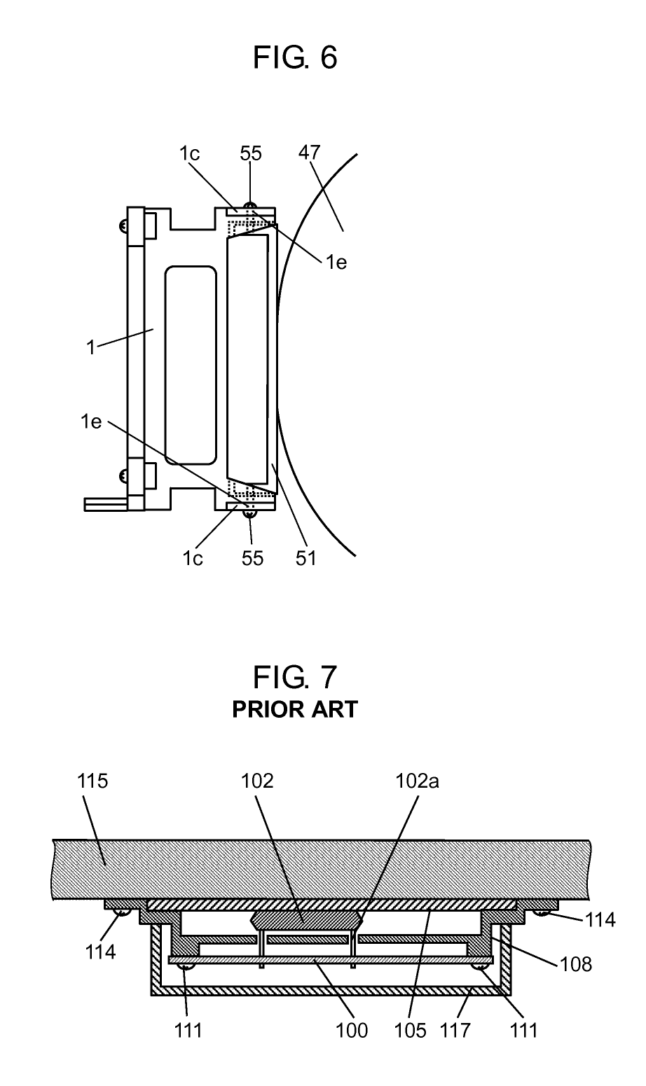

FIG. 6 is a lateral view of the electronic circuit device, in accordance with this embodiment, mounted to a compressor. As shown in FIG. 6, bracket 51 is welded onto an outer shell of hermetic compressor 47. The electronic circuit device in accordance with this embodiment is used for driving compressor 47. Mounting legs 1c of housing 1 are fixed to bracket 51 with screws 55 extending through holes 1e.

Operation and effect of the foregoing electronic circuit device are demonstrated hereinafter.

The electronic circuit device is assembled in this way: First, rubber bushings 19 are inserted into projections la of housing 1 shown in FIG. 1. Second, connector 13 is disposed oppositely to wire-outlet 17 from which the wires of connector 13 are routed out. Printed circuit board 5 is put into housing 1 through opening 9 such that it can be electrically connected to the outside. At this time, board 5 are disposed within housing 1 such that projections 1a of housing 1 can fit into mounting holes 5a.

Insulating sheets 29 are disposed on aluminum plate 21 in the following manner: Insulating sheets 29 are disposed on the underside, which confronts insulating sheets 29, of aluminum plate 21 at the section surrounded by protrusions 21b with screw 31. When screw 31 is tightened, insulating sheets 29 tend to rotate on screw 31 along the tightening direction of screw 31; however, insulating sheets 29 are prevented from rotating by protrusions 21b, so that they can be disposed on aluminum plate 21 at a correct position. Thermo-diffusion compound 35 is applied in advance to insulating sheet 29 on a face confronting to aluminum plate 21.

Next, aluminum plate 21 provided with insulating sheets 29 is mounted to housing 1 at opening 9 with screws 25. At this time, the top face of semiconductor element 39 slightly protrudes vertically from opening 9, e.g. by approx. 2 mm. Semiconductor element 39 is thus pressed by aluminum plate 21, and rubber bushings 19 are compressed by printed circuit board 5.

The electronic circuit device thus assembled is electrically powered, and then drives the compressor, whereby semiconductor element 39 generates heat, which then travels to aluminum plate 21 solidly contact with element 39 and dissipates outside housing 1.

As discussed above, this embodiment employs insulating sheets 29 between aluminum plate 21 and semiconductor element 39. If semiconductor element 39 malfunctions and its insulation is broken down, this structure allows maintaining the insulation between element 39 and plate 21. Therefore, if a user touches aluminum plate 21, the user never gets an electric shock. The electric circuit device with greater safety can be thus obtained.

A change in the ambient temperature of the electric circuit device will cause thermal expansion or contraction to housing 1; however, compressed rubber bushings 19 can absorb a variation in the dimensions of housing 1, so that a constant space between printed circuit board 5 and aluminum plate 21 can be maintained. As a result, the solid contact between semiconductor element 39, aluminum plate 21, and insulating sheets 29 can be maintained. This structure thus prevents the temperature of semiconductor device 39 from rising excessively, thereby improving the reliability of the electronic circuit device.

Printed circuit board 5 is not tightly fixed to housing 1 with, e.g. screws, but it is held flexibly with rubber bushings 19. When the electronic circuit device is mounted to an oscillatory product such as a compressor, rubber bushings 19 can absorb the oscillation, and as a result, this structure allows preventing board 5 or the components mounted to board 5 from breakdown, and the electronic circuit device can improve the reliability.

Semiconductor element 39 is mounted on the face opposite to the other face where other components are mounted. Semiconductor element 39 is mounted and the highest on upper face 5b. This structure saves element 39 from being lifted, by providing element 39 with longer terminals, to a higher position than other components from printed circuit board 5. As a result, semiconductor element 39 can be mounted with ease, so that the electronic circuit device can be assembled efficiently at a lower cost.

The mounting of rubber bushings 19 to housing 1 can be done only by fitting or inserting projections la of housing 1 into hollows 19a of rubber bushings 19. Projections 1a are formed inside housing 1 toward opening 9, and they are inserted into hollows 19a as well as mounting holes 5a of printed circuit board 5, so that rubber bushings 19 and board 5 are disposed within housing 1. Projections 1a thus can position printed circuit board 5 when it is mounted to housing 1, so that the assembly of the electronic circuit device can be done more efficiently.

Multiple protrusions 21b are formed on the surface, confronting insulating sheet 29, of aluminum plate 21 for positioning the sheet 29, which can be thus placed at a given place positively with only screw 31 due to the presence of multiple protrusions 21b. As a result, insulating sheets 29 can be mounted at a correct place more efficiently. The electronic circuit device with more safety against an electric shock is thus obtainable.

On top of that, the contact face between insulating sheet 29 and aluminum plate 21 is coated with thermo-diffusion compound 35, so that if aluminum plate 21 is deformed, a gap produced between sheet 29 and plate 21 can be covered with compound 35. The heat generated from semiconductor element 39 thus travels to aluminum plate 21 without fail. As a result, an excessive temperature rise in element 39 can be prevented, and the electronic circuit device with the higher reliability is thus obtainable.

Spacer 43 is solidly disposed between printed circuit board 5 and semiconductor element 39. This structure allows preventing rubber bushings 19 from applying compression force directly to the terminals of semiconductor element 39. As a result, the breakdowns at connection parts of the terminals of element 39 can be prevented, and the electronic circuit device with the higher reliability is thus obtainable.

What is claimed is:

1. An electronic circuit device comprising:
a printed circuit board including an upper face and a lower face, both the faces available for mounting a component;
a semiconductor element mounted on the upper face;
a housing for accommodating the printed circuit board and having an opening in one of the surfaces;
a plurality of rubber bushings disposed inside the housing for underpinning the printed circuit board in a vertical direction;
an aluminum plate disposed vertically above the printed circuit board and closing the opening; and
an insulating sheet disposed between the semiconductor element and the aluminum plate,
wherein mounting of the aluminum plate to the housing causes the printed circuit board to compress the rubber bushings, and bring the semiconductor element, the aluminum plate and the insulating sheet into pressed contact with one another.

2. The electronic circuit device of claim 1, wherein the semiconductor element is mounted and the highest on the upper face of the printed circuit board.

3. The electronic circuit device of claim 1, wherein a projection formed inside the housing toward the opening is inserted into a hollow of the rubber bushing and a mounting hole provided in the printed circuit board, so that the rubber bushing and the printed circuit board are disposed within the housing.

4. The electronic circuit device of claim 1, wherein the aluminum plate has a plurality of protrusions formed on a face confronting the insulating sheet for positioning of the insulating sheet.

5. The electronic circuit device of claim 1, wherein the insulating sheet is coated with a thermo-diffusion compound.

6. The electronic circuit device of claim 1 further comprising a spacer disposed between the printed circuit board and the semiconductor element.
